(19) United States
(12) Patent Application Publication
(10) Pub. No.: US 2023/0318208 A1
(43) Pub. Date: Oct. 5, 2023

(54) ELECTRIC CONTACT ASSEMBLY, PRINTED CIRCUIT BOARD ASSEMBLY, AND METHOD FOR PRODUCING SAME

(71) Applicant: Robert Bosch GmbH, Stuttgart (DE)

(72) Inventors: Andreas Otto, Hoerselberg-Hainich (DE); Andreas Meier, Pfullingen (DE); Matthias Raff, Balingen (DE)

(21) Appl. No.: 18/022,908

(22) PCT Filed: Jul. 29, 2021
(86) PCT No.: PCT/EP2021/071251

§ 371 Date: Feb. 23, 2023

(30) Foreign Application Priority Data
Aug. 31, 2020 (DE) 10 2020 210 961.3

(51) Int. Cl. H01R 12/58; H01R 12/52; H05K 3/36; H01R 43/02

(52) U.S. Cl. CPC H01R 12/58; H01R 12/52; H05K 3/368; H01R 43/0256

(57) ABSTRACT

The invention relates to an electric contact assembly for electrically contacting a printed circuit board or the like, comprising an installation ring (3) with an opening (3a), said installation ring (3) being designed to be fixed to the printed circuit board (11), and comprising a press-in pin (2) with a first zone (21) and a second zone (22), wherein the first zone (21) has a greater degree of mechanical flexibility than the second zone (22), and the first zone (21) is designed to be connected to another electronic component. The second zone (22) is assembled in the opening (3a) of the installation ring (3) by means of a first interference fit (4).

### BACKGROUND

The present invention relates to an electric contact assembly for electrically contacting elements of a printed circuit board assembly or the like, and to a printed circuit board assembly comprising such an electric contact assembly and a method for the production thereof.

Electric contact assemblies can be assigned to the cold contacting technology category, for example, in which electrical contact takes place in a non-releasable force-locking and form-locking manner. Electrical contact is hereby established solely by pressing or clamping the parts to be joined together. Such press-fit connections are used in printed circuit boards, for example in control devices for vehicles or the like. This results in a large number of variants ranging from individual pins to large connector strips comprising several hundred electrical contacts. In particular in the case of a large number of pins to be pressed in, the demands on the accuracy of the pins and the accuracy of the printed circuit board and also the positioning during the pressing process increase. Another set of problems arise from the fact that so-called IMS (insulated metal substrate) printed circuit boards are being used more and more, in which a base region made of an electrically conductive material and an insulation layer applied to it are employed. Because of the technological requirements, it is not possible to produce a through-contact using press-in pins. A variety of connection concepts, for example cables or SMD press-fit pins, are used to establish a connection between the IMS power electronics and other printed circuit boards or electronic elements. Cable solutions always require a complex contacting process or an expensive plug that occupies a large amount of installation space. DE 10 2008 007 310 B4 also discloses an SMD press-fit pin which is held in position by means of templates during soldering. Providing and removing the template interrupts the SMD production process, however, and thus leads to increased production costs and processing times.

### SUMMARY

Compared to this, the electric contact assembly according to the invention for electrically contacting a printed circuit board or the like has the advantage that a very cost-efficient and reliable electrical contacting solution has been found. The electrical contacting can in particular be integrated in an SMD production without special processes or complex and time-consuming production steps. The electric contact assembly according to the invention requires only a minimum amount of installation space and further enables a free configuration of the contacting, in particular with regard to a position and a number of electrical contacts. The electric contact assembly can also be flexibly adapted to a wide variety of requirements during the production of printed circuit boards or the like. Thanks to the simple and precise joining processes, the invention also makes it possible to reduce a tolerance chain. The joining processes can be carried out at ambient temperature. This also enables simple process management and monitoring of the electrical contacting. According to the invention, this is achieved in that the electric contact assembly comprises an installation ring having an opening and also a press-in pin. The installation ring is configured to be fastened to the printed circuit board or the like. The installation ring can be incorporated into the SMD production process as an SMD component. The press-in pin comprises a first and a second zone. The first zone has a greater mechanical flexibility than the second zone. The press-in pin therefore comprises a first flexible zone and a second rigid zone. The first flexible zone is configured to be fastened to a further electronic component, for example a second printed circuit board. The second, more rigid, zone is fitted in the opening of the installation pin by means of a first interference fit.

According to the invention, a printed circuit board is understood to mean a circuit carrier, for example a PCB (printed circuit board) made of FR4 material, or a circuit carrier made of ceramic substrates (LTCC (low-temperature co-fired ceramics), DBC (direct bonded copper)) and other FR materials.

The electric contact assembly can thus be provided in a first step by fastening the installation ring to a printed circuit board, in particular an IMS printed circuit board, and a subsequent joining step of the press-in pin into the opening of the installation ring. In a further joining step, the electrical connection between the first printed circuit board and a second printed circuit board or the like can then be continued by joining the press-in pin on the first, more flexible, zone to the second printed circuit board.

The installation ring can easily be produced as a punched component comprising a central opening for the first press connection, for example. If necessary, the installation ring can be coated by means of a galvanic process. The fastening of the installation ring can then be integrated into a standardized SMD production. The installation ring can be fitted to a surface using a variety of joining processes, for example using a soldering process. After fastening the installation ring, the press-in pin can then be fitted in the opening of the installation ring by means of the first press connection. This makes it possible to ensure very precise positioning of the electric contact assembly on the printed circuit board.

The press-in pin, comprising the first and the second zone, is preferably made in one piece of one material. The press-in pin is preferably made of a wire material or strip material having a thickness of 0.4 to 0.8 mm.

The first, more flexible, zone of the press-in pin is preferably produced by geometrically reshaping the base material of the press-in pin. The first zone is thus a geometric forming region, which can, for instance, be an oval eyelet or a ring or the like.

The second zone, which is less flexible than the first zone of the press-in pin, is preferably a solid material region, for example a cylindrical region of the base material of the press-in pin.

The press-in pin further preferably comprises a press-in aid. The press-in aid is preferably disposed on the second zone of the press-in pin, which has a lesser flexibility. The press-in aid is particularly preferably a peripheral annular flange. The press-in aid is preferably fastened to the second, more rigid, zone by means of soldering or welding, for example. Alternatively, the press-in aid and the second zone are made of a single material.

The flexible first zone is further preferably configured for a second interference fit with the further electronic component. The press-in pin of the electric contact assembly thus comprises two press connection regions.

The present invention also relates to a printed circuit board assembly comprising at least a first printed circuit board, which has a base region made of an electrically conductive material and an insulation layer on said base region made of an electrically non-conductive material and includes an electric contact assembly according to the invention. The printed circuit board is preferably an IMS printed circuit board and further preferably a printed circuit board produced by means of SMD production.

This makes it possible to integrate the installation ring into the SMD production process as an SMD component to be assembled and to integrate the fastening of the installation ring within the usual SMD process.

The printed circuit board assembly preferably comprises a plurality of electric contact assemblies according to the invention.

Further preferably, a solder connection is configured between the installation ring and the printed circuit board of the printed circuit board assembly. The solder connection is particularly preferably a reflow solder connection. This allows the installation ring to be mounted on the surface of the insulation layer of the printed circuit board in a simple and cost-efficient manner.

According to a particularly preferred configuration of the invention, the printed circuit board assembly further comprises a second printed circuit board or the like, wherein the flexible first zone of the press-in pin is connected to the second printed circuit board by means of a second press connection. Instead of the printed circuit boards, electrical contacting can of course also be provided by other components using the electric contact assembly according to the invention.

The first printed circuit board is preferably an IMS printed circuit board and preferably comprises an electrically insulating insulation layer on only one side of a metal substrate or the like.

The insulation layer is preferably made of a flame-retardant composite material and is in particular an FR4 layer.

With the printed circuit board assembly according to the invention, it is thus also possible to quickly and cost-efficiently implement a plurality of plug connections using the electric contact assembly with the first and the second zone.

The printed circuit board assembly is preferably used in a control device of vehicles.

The present invention further relates to a method for producing a printed circuit board assembly comprising a first printed circuit board made of an insulated metal substrate, in particular an IMS printed circuit board, and a second printed circuit board or the like, comprising the steps:
providing the first printed circuit board,
carrying out an SMD production (surface-mount device production) for fastening at least one SMD component and at least one installation ring of an electric contact assembly according to the invention within the SMD process,
pressing a press-in pin of the electric contact assembly into the installation ring fastened to the first printed circuit board, so that a first press connection is configured between the press-in pin and the installation ring, and
pressing a second printed circuit board or the like onto the at least one press-in pin on the first printed circuit board to produce a second press connection between the press-in pin and the second printed circuit board.

The method according to the invention thus makes it possible for electric contact assemblies to be fastened within an SMD production. The installation ring of the electric contact assembly is therefore an SMD component, so that the assembly enables simple process management and monitoring. The installation rings can, for example, be fed to the printed circuit board as bulk material via a corresponding feed device, e.g., a pick-and-place machine, and fastened to it, in particular by means of soldering.

### BRIEF DESCRIPTION OF THE DRAWINGS

A preferred design example of the invention is described in detail in the following with reference to the accompanying drawing. The drawing shows:

FIG. 1 a schematic side view of a press-in pin of an electric contact assembly according to a preferred design example of the invention,

FIG. 2 a plan view of an installation ring of the electric contact assembly,

FIG. 3 is a schematic sectional view of the entire electric contact assembly, and

FIG. 4 a schematic sectional view of a printed circuit board assembly with a plurality of electric contact assemblies according to FIGS. 1 to 3.

### DETAILED DESCRIPTION

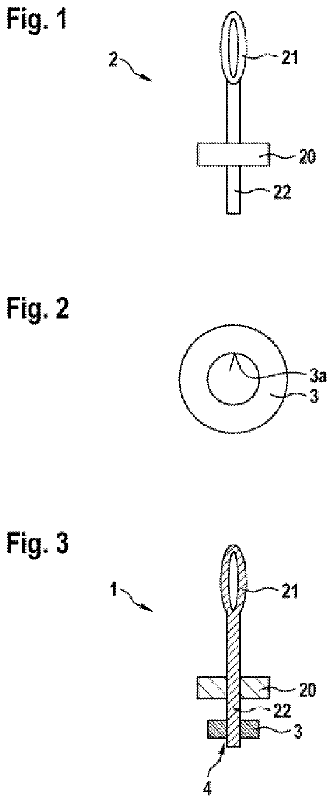

An electric contact assembly 1 and a printed circuit board assembly 10, and a method for producing a printed circuit board assembly according to a preferred design example of the invention, will be described in detail in the following with reference to FIGS. 1 to 4.

FIGS. 1 to 3 show the electric contact assembly 1 according to the invention. The electric contact assembly comprises two main components, namely an installation ring 3 (FIG. 2) and a press-in pin 2, which can be seen in detail in FIG. 1. FIG. 3 shows the assembled state of the installation ring 3 with the press-in pin 2.

The installation ring 3 is a closed ring made of an electrically conductive material, preferably metal. The installation ring 3 comprises an inner opening 3a. The inner opening 3a is configured to receive the press-in pin 2.

The press-in pin 2 comprises a first zone 21 and a second zone 22. The first zone 21 has greater mechanical flexibility than the second zone 22. The second zone 22 is thus the stiffer zone of the press-in pin. The second zone 22 is substantially a cylindrical solid material pin.

In this design example, the first zone 21 is a region that has been geometrically reshaped out of its initial shape, e.g., a cylindrical pin, and is configured as an oval eyelet. Raw material at a free end of the raw material can be reshaped to form a region of the first zone 21 which has been geometrically reshaped into a closed eyelet and the raw material can then be cut to a desired length of the press-in pin. This creates the second zone 22, which can be untreated raw material, for example a wire material.

The press-in pin 2 further comprises a press-in shoulder 20, which in this design example is a peripherally closed ring that is fastened to the second stiffer zone 22 of the press-in pin 2. This can be accomplished via a solder connection or a weld connection, for example.

FIG. 1 shows a side view of the finished press-in pin 2 with the first zone 21, the rod-shaped, stiffer second zone 22 and the press-in shoulder 20.

It should be noted that the first zone 21 can also be produced by fastening an eyelet or a ring made of a different material to a rod-shaped material that provides the second zone 22 of the press-in pin 2.

FIG. 3 shows the installed state, in which the press-in pin 2 is pressed into the opening 3a of the installation ring 3. This results in a first press connection 4 between the installation ring 3 and the press-in pin 2 in the region of the second free end of the press-in pin 2.

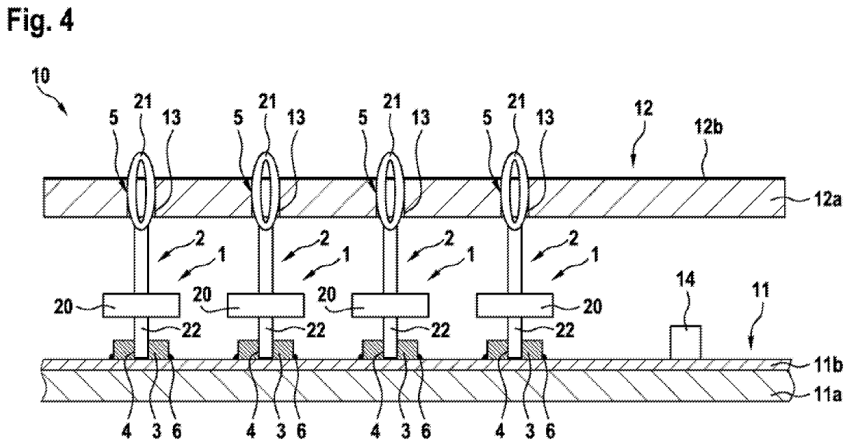

FIG. 4 shows the printed circuit board assembly 10 with a plurality of electric contact assemblies 1. The printed circuit board assembly 10 comprises a first printed circuit board 11 and a second printed circuit board 12 which is disposed at a distance above the first printed circuit board 11. The printed circuit board assembly 10 also comprises a plurality of electric contact assemblies 1. The method according to the invention is explained with reference to FIG. 4 as well.

As can be seen from FIG. 4, the first printed circuit board 11 is an IMS printed circuit board comprising a metal body 11a and an insulation layer 11b made of an FR4 material. A plurality of electronic components 14 can be fastened to the FR4 material using SMD technology. FIG. 4 schematically shows an SMD component 14 fastened to the insulation layer 11b. The installation ring 3 of the electric contact assembly 1 is likewise provided as an SMD component and is fastened to the surface of the insulation layer 11b by means of a solder connection 6. This makes it possible to integrate the fastening of the installation ring 3 into the already existing SMD production process. The production of the first printed circuit board 11 can thus be carried out in a very cost-efficient manner and in a very short time.

To complete the electric contact assembly, the press-in pin 2 is now pressed into the installation ring 3 fastened to the surface of the insulation layer 11b, so that the first press connection 4 between the installation ring 3 and the press-in pin 2 is configured. This is accomplished using a not-depicted press-in tool, which engages on the press-in shoulder 20 of the press-in pin 20.

The press-in pins 1 can be pressed into a respective installation ring 3 individually, or a plurality of press-in pins 2 are pressed into respective installation rings 3 in parallel.

In a final step, the second printed circuit board 12 is then pressed onto the press-in pins 2 projecting from the surface of the first printed circuit board 11. To do this, the first zones 21 are inserted into passage openings 13 in the second printed circuit board 12 so that a second press connection 5 is respectively configured between the first zone 21 of the press-in pin 2 and the second printed circuit board 12.

The second printed circuit board 12 comprises an insulation carrier 12a made of an FR4 material and electrical lines 12b on a surface of the insulation carrier 12a.

Thus, according to the invention, a large number of electrical contact-connections between the first printed circuit board 11 and the second printed circuit board 12 can be achieved in a single step. The press-in pins 2 are preferably all configured identically.

A printed circuit board assembly 10 can thus be produced while continuing to use a conventional SMD production process without special processes. The electrical contacting can be configured freely, in particular with regard to position and number, is possible. It is also possible to adapt quickly to a wide variety of requirements, or to switch production to a different printed circuit board assembly. The joining steps can be carried out without a heat treatment of the printed circuit boards 11, 12. This, too, results in simple process management and monitoring.

1. An electric contact assembly comprising:
an installation ring (3) having an opening (3a), wherein the installation ring (3) is configured to be fastened to the printed circuit board (11), and
a press-in pin (2) having a first zone (21) and a second zone (22), wherein the first zone (21) has greater mechanical flexibility than the second zone (22),
wherein the first zone (21) is configured to be connected to a further electronic component, and
wherein the second zone (22) is fitted in the opening (3a) of the installation ring (3) by a first interference fit (4).

2. The electric contact assembly according to claim 1, wherein the press-in pin (2) is made in one piece of one material.

3. The electric contact assembly according to claim 1, wherein the first zone (21) of the press-in pin (2) is a geometrically reshaped region.

4. The electric contact assembly according to claim 1, wherein the second zone is made of a solid material.

5. The electric contact assembly according to claim 1, further comprising a press-in aid (20) disposed on the second zone (22).

6. The electric contact assembly according to claim 1, wherein the first zone (21) is configured for a second interference fit (5) with the further electronic component.

7. A printed circuit board assembly comprising:
a first printed circuit board (11) comprising a base region (11a) made of an electrically conductive material and an insulation layer (11b) which is disposed on said base region (11a) and is made of an electrically non-conductive material, and
an electric contact assembly (1) according to claim 1,
wherein the installation ring (3) of the electric contact assembly (1) is fastened to the insulation layer (11b).

8. The printed circuit board assembly according to claim 7, wherein a solder connection or a weld connection is configured between the first printed circuit board (11) and the installation ring (3).

9. The printed circuit board assembly according to claim 7, further comprising a second printed circuit board (12), wherein a second press connection (5) is configured between the second printed circuit board (12) and the first zone (21) of the press-in pin (2).

10. The printed circuit board assembly according claim 7, wherein the first printed circuit board (11) is made of an insulated metal substrate.

11. The printed circuit board assembly according to any one of claim 7, wherein, on one side of the base region (11a), an insulation layer (11b) is made of a flame-retardant composite material.

12. A method for producing a printed circuit board assembly (10) comprising a first printed circuit board (11) made of an insulated metal substrate, and a second printed circuit board (12) comprising the steps
providing the first printed circuit board (11),
carrying out an SMD process for fastening at least one SMD component (14) and at least one installation ring (3) of an electric contact assembly (1) within the SMD process,
pressing a press-in pin (2) into the installation ring (3) fastened to the first printed circuit board (11), so that a first press connection (4) is configured between the press-in pin (2) and the installation ring (3), wherein the press-in pin (2) comprises a first zone (21) and a second zone (22), wherein the first zone (21) is more flexible than the second zone (22) and the second zone (22) is configured on the first press connection (4), and
pressing the second printed circuit board (12) onto the at least one press-in pin (2) on the first zone (21) of the press-in pin (2) to produce a second press connection (5) between the press-in pin (2) and the second printed circuit board (12).

13. The electric contact assembly according to claim 3, wherein the geometrically reshaped region is an oval eyelet or a ring.

14. The electric contact assembly according to claim 4, wherein the second zone is made of a cylindrical solid material.

15. The electric contact assembly according to claim 5, wherein the press-in aid is a peripheral annular flange on the second zone (22).

16. The printed circuit board assembly according claim 10, wherein the first printed circuit board (11) is an IMS printed circuit board.

17. The printed circuit board assembly according to claim 11, wherein the insulation layer (11b) is made of FR4.

18. The method according claim 12, wherein the first printed circuit board (11) is an IMS printed circuit board.
